(19) United States
(12) Patent Application Publication
(10) Pub. No.: US 2007/0256732 A1
(43) Pub. Date: Nov. 8, 2007

(54) Photovoltaic module

(76) Inventor: Ming-Hsien Shen, Tapei Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/415,744

(22) Filed: May 2, 2006

(51) Int. Cl. H01L 31/00

(52) U.S. Cl. 136/256

(57) ABSTRACT

A photovoltaic module includes at least one photovoltaic cell and a transparent layer. The transparent layer is positioned above the photovoltaic cell, wherein the transparent layer has a plurality of protruding parts arranged on at least one surface of the transparent layer, which faces the outside, inside or both of the photovoltaic module.

### BACKGROUND

1. Field of Invention

The present invention relates to a photovoltaic module. More particularly, the present invention relates to a photovoltaic module with a bumpy transparent layer for enhancing the photovoltaic effect.

2. Description of Related Art

A photovoltaic cell, or solar cell, is a semiconductor device consisting of a large area of p-n junction diode, which in the presence of light is capable of generating usable electrical energy. This conversion is called the photovoltaic effect. When light hits the photovoltaic cell and is absorbed by the p-n junction diode, electrons will be knocked loose from their atoms, allowing them to flow through materials to produce electricity.

Photovoltaic cells have many applications. They are particularly well suited to, and historically used in, situations where electrical power from the grid is unavailable, such as in remote area power systems, Earth orbiting satellites, handheld calculators, remote radiotelephones and water pumping applications. Photovoltaic cells (in the form of photovoltaic modules or solar panels) on building roofs can be connected through an inverter to the electricity grid in a net metering arrangement.

Usually, photovoltaic cells are electrically connected, and combined into “a photovoltaic module”, or a solar panel. Reference is made to FIG. 1 which is a schematic diagram illustrating a part of a conventional photovoltaic module. In FIG. 1, a photovoltaic module 100 includes a photovoltaic cell 110 and two spacers 120 adjacent to the photovoltaic cell 110 for defining the edge of the photovoltaic cell 110. Typically, the photovoltaic module 100 further has a transparent layer 130 (such as a sheet of glass) positioned above the photovoltaic cell 110 to keep the photovoltaic cell 110 safe from the elements (rain, hail, etc). This transparent layer 130 generally is flat, but the incident angle of the light applied to the transparent layer 130 is usually varied. For example, when the photovoltaic module 100 is employed by vehicles or buildings as power sources, the incident angle of sunlight applied to the transparent layer 130 in the morning and noon are different. Thus, parts of light 140 with larger incident angle may be reflected to the outside of the photovoltaic module 100. Even if light penetrates the transparent layer 130, another parts of light 150 will hit the spacer 120 where is incapable of producing electricity. That is, the parts of light 140 or 150 will be lost due to the reflection of the transparent layer 130 or the spacer 120 even through they have hit the photovoltaic module 100. Therefore, the electric power generating efficiency of the photovoltaic module is still not enough to replace traditional power sources, ex thermal power plants, at the present day.

### SUMMARY

It is therefore an aspect of the present invention to provide a photovoltaic module with a bumpy transparent layer for enhancing the photovoltaic effect.

In accordance with the foregoing aspect of the present invention, a photovoltaic module including at least one photovoltaic cell and a transparent layer is provided. The transparent layer is positioned above the photovoltaic cell, wherein the transparent layer has a plurality of protruding parts arranged on at least one surface of the transparent layer, which faces the outside, inside or both of the photovoltaic module.

From another aspect of the photovoltaic module, the transparent layer of the photovoltaic module may also be seen as having a plurality of trenches arranged on the surface of the transparent layer. Although parts of light are still reflected by the transparent layer, the parts of light are reflected to the photovoltaic cell due to the protruding parts or the trenches, so more light, compared with a conventional photovoltaic module, will be absorbed by the photovoltaic cell to enhance the photovoltaic effect.

Each of the protruding parts or the trenches may have a protruding part or trench surface with a plurality of nano-structures, such as bumps, fully arranged thereon. Each of the bumps may have at least one dimension less than 100 nm. When the bumps are in nanoscale size range, lotus effect will occur on the surface, that is, the surface will have the characteristic of self-cleaning.

It is another aspect of the present invention to provide a photovoltaic module with a curved transparent layer for focusing light onto the photovoltaic cell.

In accordance with the foregoing aspect of the present invention, a photovoltaic module including at least one photovoltaic cell, at least one spacer and a transparent layer is provided. The spacer is adjacent to the photovoltaic cell. The transparent layer is positioned above the photovoltaic cell, wherein the transparent layer has at least one curved surface. Thus, parts of light, would hit the spacer if the transparent layer were flat as mentioned above, are focused onto the photovoltaic cell to enhance the photovoltaic effect.

In conclusion, the photovoltaic module according to the present invention has higher electric power generating efficiency than a conventional photovoltaic module because light, which can't be used by the conventional photovoltaic module, can be used by the photovoltaic module of the present invention. Therefore, the photovoltaic module according to the present invention may be applied to replace traditional power sources, ex thermal power plants.

It is to be understood that both the foregoing general description and the following detailed description are by examples, and are intended to provide further explanation of the present invention as claimed.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention. In the drawings,

FIG. 1 is a schematic diagram illustrating a part of a conventional photovoltaic module;

FIG. 2A is a schematic diagram illustrating a part of a photovoltaic module according to one preferred embodiment of the present invention;

FIG. 2B is a schematic diagram illustrating a part of a photovoltaic module according to another preferred embodiment of the present invention;

FIG. 2C is a top view of the photovoltaic module 200 shown in FIG. 2A;

FIG. 2D is a top view of the photovoltaic module according to another embodiment of the present invention;

FIG. 2E is a top view of the photovoltaic module according to still another embodiment of the present invention;

FIG. 2F is an enlarged schematic diagram illustrating the cross section viewed along the I-I′ line in FIG. 2D;

FIG. 3A is a schematic diagram illustrating a part of a photovoltaic module according to yet another preferred embodiment of the present invention;

FIG. 3B is a schematic diagram illustrating a part of a photovoltaic module according to still another preferred embodiment of the present invention; and

FIG. 3C is a schematic diagram illustrating a part of a photovoltaic module according to further another preferred embodiment of the present invention.

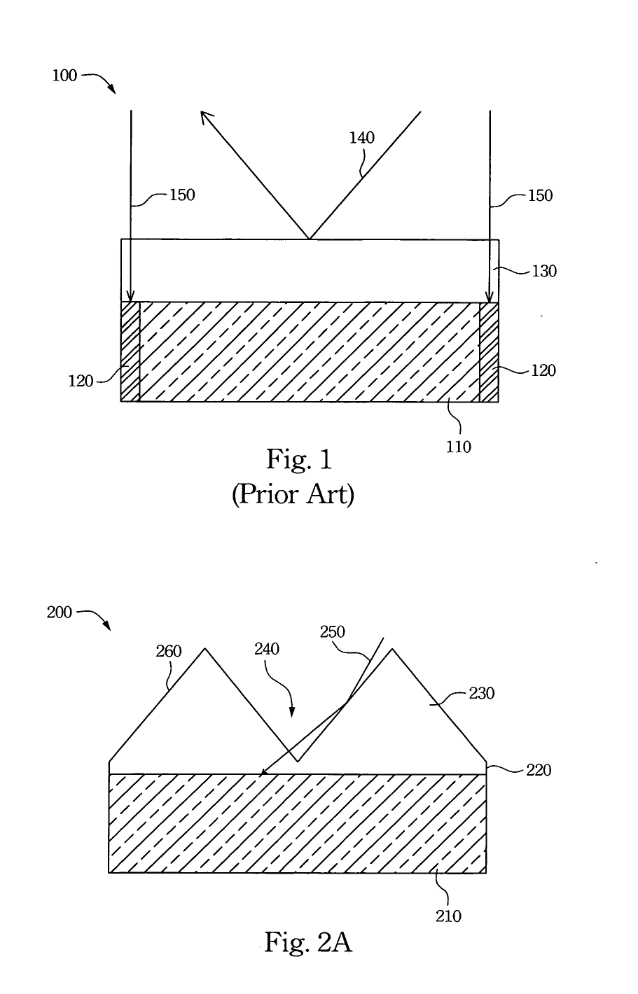

### DESCRIPTION OF THE PREFERRED EMBODIMENTS

Reference will now be made in detail to the present preferred embodiments of the present invention, examples of which are illustrated in the accompanying drawings. Wherever possible, the same reference numbers are used in the drawings and the description to refer to the same or like parts.

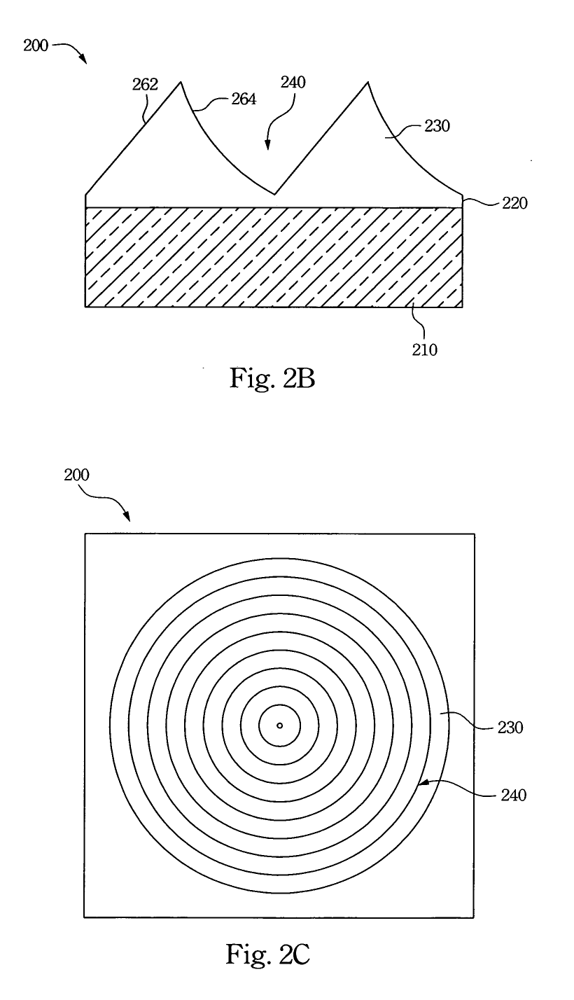

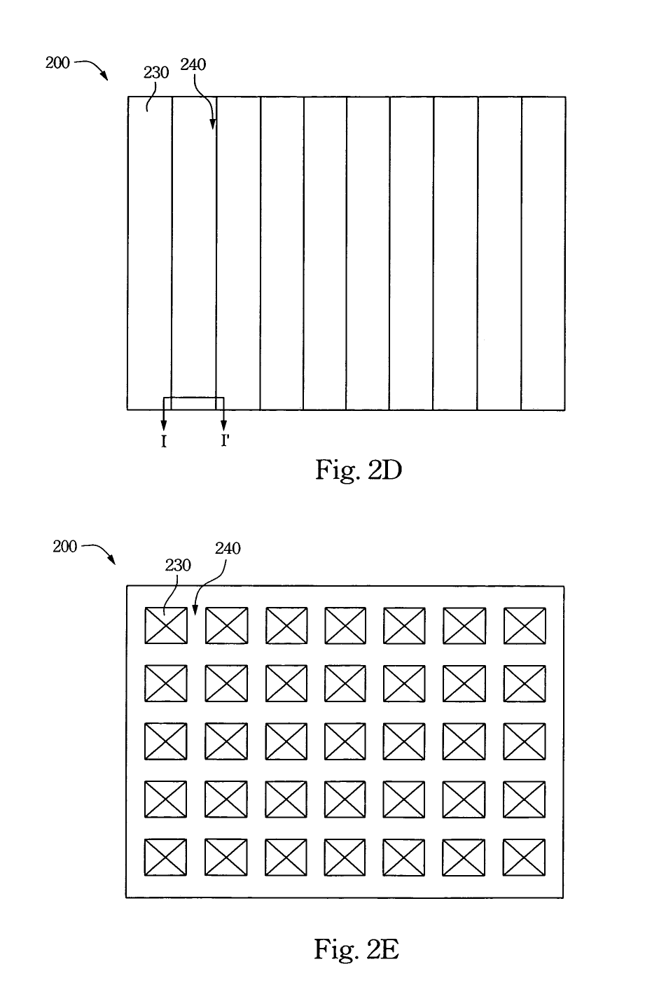

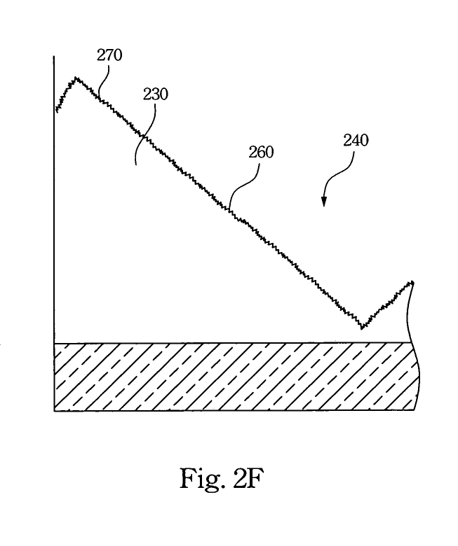

Reference is made to FIG. 2A which is a schematic diagram illustrating a part of a photovoltaic module according to one preferred embodiment of the present invention. In FIG. 2A, a photovoltaic module 200 including at least one photovoltaic cell 210 and a transparent layer 220 is provided. The transparent layer 220 is positioned above the photovoltaic cell 210, wherein the transparent layer 220 has a plurality of protruding parts 230 arranged on a surface of the transparent layer 220 which faces the outside of the photovoltaic module 200. Although the surface of the transparent layer 220 which the protruding parts 230 are arranged on faces the outside of the photovoltaic module in FIG. 2A, the protruding parts may also be arrange on another surface of the transparent layer which faces the inside of the transparent layer.

From another aspect of the photovoltaic module 200, the transparent layer 220 of the photovoltaic module 200 may also be seen as having a plurality of trenches 240 arranged on the surface of the transparent layer 220 which faces the outside of the photovoltaic module 200. Although parts of light 250 are still reflected by the transparent layer 220, the parts of light 250 are reflected to the photovoltaic cell 210 due to the protruding parts 230 or the trenches 240, so more light, compared with a conventional photovoltaic module, will be absorbed by the photovoltaic cell 210 to enhance the photovoltaic effect.

As shown in FIG. 2A, each of the protruding parts 230 has a V shaped section. However, each of the protruding parts according to the present invention may also have a convex section. Furthermore, each of the protruding parts 230 may have a plane surface 262 and a curved surface 264 (as shown in FIG. 2B). In some illustrating embodiment, each of the protruding parts may have a convex surface or a concave surface. Generically, the section of each of the protruding parts may be any shapes, which has the ability to reflect the parts of light to the photovoltaic cell.

Reference is made to FIG. 2C which is a top view of the photovoltaic module 200 shown in FIG. 2A. In FIG. 2C, the protruding parts 230 are arranged in a pattern of concentric circles. However, the protruding parts according to the present invention may be arranged in any patterns, which have the ability to reflect the parts of light to the photovoltaic cell. For example, the protruding parts 230 shown in FIG. 2D are arranged in a pattern of beelines.

In FIG. 2D, each of the protruding parts 230 has a shape of triangular prism. However, each of the protruding parts according to the present invention may be any shapes, which has the ability to reflect the parts of light to the photovoltaic cell. For example, each of the protruding parts 230 shown in FIG. 2E has a shape of tetrahedron, and the protruding parts 230 shown in FIG. 2E are spaced out a distance apart, wherein the distance is less than about 10 mm.

Reference is made to FIG. 2F which is an enlarged schematic diagram illustrating the cross section viewed along the I-I′ line in FIG. 2D. As shown in FIG. 2F, each of the protruding parts 230 or the trenches 240 may have a protruding part or trench surface 260 with a plurality of nano protruding structures, such as bumps 270, fully arranged thereon. Each of the bumps 270 may has at least one dimension less than 100 nm. When the bumps 270 are in nanoscale size range, lotus effect will occur on the surface 260, that is, the surface 260 will have the characteristic of self-cleaning. The surface of protruding parts 230 illustrated in FIGS. 2C and 2E may have the nano-structures as well.

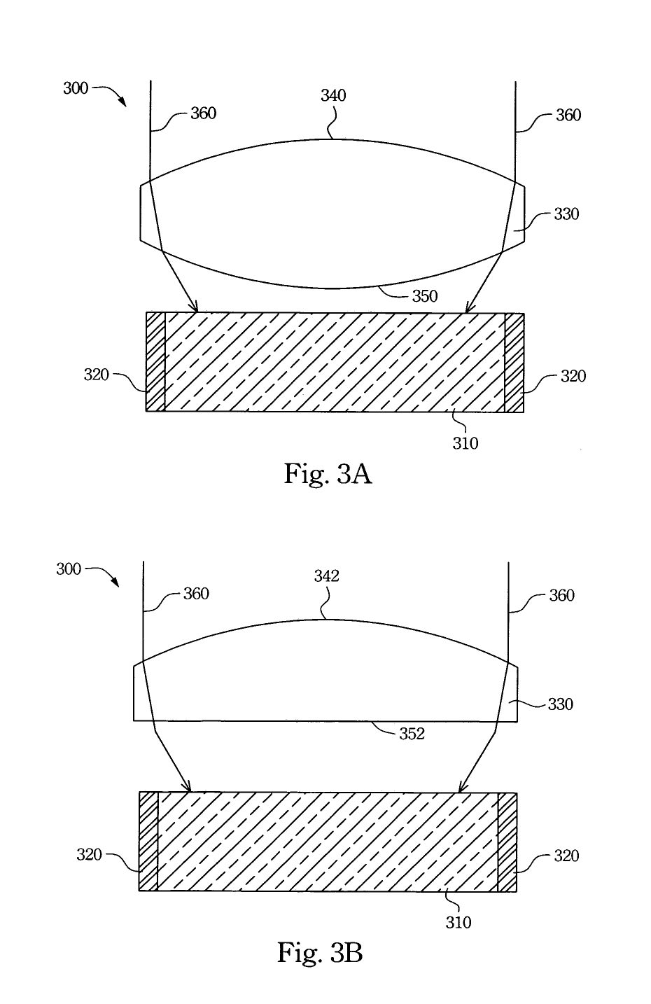

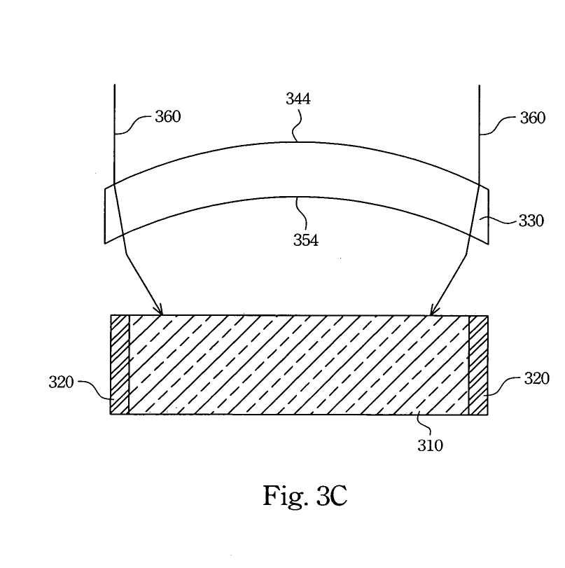

Reference is made to FIG. 3A which is a schematic diagram illustrating a part of a photovoltaic module according to another preferred embodiment of the present invention. In FIG. 3A, a photovoltaic module 300 includes a photovoltaic cell 310, two spacers 320 and a transparent layer 330. The spacers 320 are adjacent to the photovoltaic cell 310 for defining the edge of the photovoltaic cell 310. The transparent layer 330 is positioned above the photovoltaic cell 310, wherein the transparent layer 330 has an outer curved surface 340 and an inner curved surface 350. Thus, parts of light 360, would hit the spacer 320 if the transparent layer 330 were flat as mentioned above, are focused onto the photovoltaic cell 310 to enhance the photovoltaic effect. Although the transparent layer 330 has the outer curved surface 340 and the inner curved surface 350 shown in FIG. 3A, the transparent layer according to the present invention may have a single curved surface, which faces the outside or the inside of the photovoltaic module, and another surface of the transparent layer may be a flat surface. For example, the transparent layer 330 shown in FIG. 3B has an outer convex surface 342 and an inner flat surface 352.

Reference is made to FIG. 3A, again. The outer curved surface 340 or the inner curved surface 350 of the transparent layer 330 are convex surfaces. However, the curved surface(s) of the transparent layer according to the present invention may be a concave surface. For example, the transparent layer 330 shown in FIG. 3C has an outer convex surface 344 and an inner concave surface 354. Moreover, the curved surface(s) of the transparent layer may be a spherical surface or aspheric surface. Generically, the curved surface(s) of the transparent layer may be any kinds of curved surface, which have the ability to focus light onto the photovoltaic cell.

Although the present invention has been described in considerable detail with reference certain preferred embodiments thereof, other embodiments are possible. For example, the transparent layer 330 shown in FIG. 3A may have a plurality of bumps arranged on the outer curved surface 340, and the detailed arrangement and size of the bumps are the same as mentioned earlier. Moreover, the curved surfaces and the photovoltaic cells according to the present invention may be arranged one to one, one to many or many to one. In addition, the transparent layer of the present invention may be made of glass, plastics or acrylic material. Therefore, their spirit and scope of the appended claims should no be limited to the description of the preferred embodiments container herein.

The photovoltaic module according to the present invention has higher electric power generating efficiency than a conventional photovoltaic module because light, which can't be used by the conventional photovoltaic module, can be used by the photovoltaic module of the present invention. Therefore, the photovoltaic module according to the present invention may be applied to replace traditional power sources, ex thermal power plants.

It will be apparent to those skilled in the art that various modifications and variations can be made to the structure of the present invention without departing from the scope or spirit of the present invention. In view of the foregoing, it is intended that the present invention cover modifications and variations of this invention provided they fall within the scope of the following claims and their equivalents.

What is claimed is:

1. A photovoltaic module comprising:
at least one photovoltaic cell; and
a transparent layer positioned above the photovoltaic cell, wherein the transparent layer has a plurality of protruding parts arranged on at least one surface of the transparent layer.

2. The photovoltaic module of claim 1, wherein each of the protruding parts has a V shaped section.

3. The photovoltaic module of claim 1, wherein each of the protruding parts has a convex section.

4. The photovoltaic module of claim 1, wherein each of the protruding parts has a plane surface and a curved surface.

5. The photovoltaic module of claim 1, wherein each of the protruding parts has a convex surface or a concave surface.

6. The photovoltaic module of claim 1, wherein the protruding parts are arranged in a pattern of concentric circles.

7. The photovoltaic module of claim 1, wherein the protruding parts are arranged in a pattern of beelines.

8. The photovoltaic module of claim 1, wherein each of the protruding parts has a shape of triangular prism.

9. The photovoltaic module of claim 1, wherein each of the protruding parts has a shape of tetrahedron.

10. The photovoltaic module of claim 9, wherein the protruding parts are spaced out a distance apart, and the distance is less than about 10 mm.

11. The photovoltaic module of claim 1, wherein each of the protruding parts has a protruding part surface having a plurality of bumps arranged thereon.

12. The photovoltaic module of claim 11, wherein each of the bumps has at least one dimension less than 100 nm.

13. The photovoltaic module of claim 11, wherein the bumps are fully arranged on the protruding surface.

14. The photovoltaic module of claim 1, wherein the transparent layer is made of glass, plastics or acrylic material.

15. A photovoltaic module comprising:
at least one photovoltaic cell; and
a transparent layer positioned above the photovoltaic cell, wherein the transparent layer has a plurality of trenches arranged on a surface of the transparent layer, which faces the outside of the photovoltaic module.

16. The photovoltaic module of claim 15, wherein each of the trenches has a trench surface having a plurality of bumps arranged thereon.

17. The photovoltaic module of claim 16, wherein the bumps are fully arranged on the trench surface.

18. A photovoltaic module comprising:
at least one photovoltaic cell;
at least one spacer adjacent to the photovoltaic cell; and
a transparent layer positioned above the photovoltaic cell, wherein the transparent layer has at least one curved surface for focusing light onto the photovoltaic cell.

19. The photovoltaic module of claim 18, wherein the curved surface of the transparent layer is a convex surface.

20. The photovoltaic module of claim 18, wherein the curved surface of the transparent layer is a concave surface.

21. The photovoltaic module of claim 18, wherein the curved surface of the transparent layer is a spherical surface.

22. The photovoltaic module of claim 18, wherein the curved surface of the transparent layer is an aspheric surface.

23. The photovoltaic module of claim 18, further comprising a plurality of bumps arranged on the curved surface of the transparent layer.

24. The photovoltaic module of claim 23, wherein each of the bumps has at least one dimension less than 100 nm.

25. The photovoltaic module of claim 23, wherein the bumps are fully arranged on the curved surface of the transparent layer.

26. The photovoltaic module of claim 18, wherein the transparent layer is made of glass, plastics or acrylic material.
